(19) United States
(12) Patent Application Publication
(10) Pub. No.: US 2025/0316256 A1
(43) Pub. Date: Oct. 9, 2025

(54) DEVICE FOR REDUCING NOISE DURING THE REPRODUCTION OF AN AUDIO SIGNAL USING A HEADPHONE OR HEARING AID, AND CORRESPONDING METHOD

(71) Applicant: ELEVEAR GMBH, Aachen (DE)

(72) Inventors: Johannes FABRY, Aachen (DE); Stefan LIEBICH, Aachen (DE); Raphael BRANDIS, Aachen (DE)

(21) Appl. No.: 18/863,078

(22) PCT Filed: May 5, 2023
(86) PCT No.: PCT/EP2023/061951

§ 371 Date: Nov. 5, 2024

(30) Foreign Application Priority Data
May 6, 2022 (DE) 10 2022 111 300.0

(51) Int. Cl. G10K 11/178

(52) U.S. Cl. CPC G10K 11/17823; G10K 11/17873; G10K 2210/1081; G10K 2210/3027; G10K 2210/3028

(57) ABSTRACT

For reducing noise when playing back an audio signal with headphones or a hearing aid, at least one sensor is provided for detecting a sensor signal based on ambient sound and/or structure-borne sound. The sensor signal or the sensor signals are first fed to a preprocessing unit for preprocessing, which carries out filtering and/or summation for active noise suppression, active suppression of the occlusion effect and/or an ambient mode. With a subsequent filter bank, the sensor signal or the output signal of the preprocessing unit is divided into frequency bands by means of several filters. One or more calculation units are provided for calculating weighting factors for the individual frequency bands, which calculate the weighting factors based on a measure of the sensor signal in the respective frequency band and a measure of the noise signal of the sensor or the output signal of the preprocessing unit in silence in this frequency band. The individual frequency bands are multiplied by the corresponding calculated weighting factors using multipliers. The weighted output signals of the filter bank are summed to form an overall output signal using an adder. A compensation signal based on the overall output signal is output using an output unit.

The present disclosure relates to a device for reducing noise during the reproduction of an audio signal with an audio output device near the head, in particular headphones or a hearing aid. The present disclosure further relates to a corresponding method.

The range of functions of modern headphones often extends far beyond listening to music or making phone calls. Active noise cancellation (ANC), which reduces the perceptibility of ambient noise by playing an acoustic compensation signal through a loudspeaker built into the headphones, is now standard equipment on such headphones. The same applies to a transparency mode provided for headphones and hearing aids, in which ambient noise is filtered and played through the loudspeaker built into the headphones in such a way that there is hardly any audible difference to the auditory sensation with open ears, i.e. without wearing the headphones. Some headphones and hearing aids in particular also have an ambient mode in which ambient noise is processed and/or amplified, for example to improve speech intelligibility or to compensate for hearing loss. However, these applications are not limited to headphones and hearing aids but can be implemented in all types of head-mounted audio output devices, such as so-called smart glasses, VR/AR headsets, collar loudspeakers or bone conduction headphones. In order to support active noise cancellation, a transparency or ambient mode, headphones are equipped with at least one external microphone, one internal microphone and optionally an acceleration sensor in addition to the loudspeaker, hereinafter referred to collectively as sensors. The processing of the microphone signals and acceleration data recorded with the external microphone, internal microphone and possibly acceleration sensor, hereinafter referred to collectively as sensor data, is usually carried out on a digital signal processor (DSP), as this is the only way to implement sufficiently powerful algorithms.

When the sensors mentioned convert acoustic sound into analog electrical signals, noise is added to the useful signal of the respective sensor. Furthermore, the analog-digital conversion of the analog electrical signals into digital signals adds quantisation noise, the power of which depends on the bit accuracy of the converter. Due to the processing and filtering of the noisy sensor data on a DSP, the noise can be amplified, which means that it can be clearly audible after playback via the loudspeaker. Users can find this unpleasant, especially in quiet environments.

The state of the art lists a whole range of methods for improving or eliminating interference from speech and useful signals. The most common are analysis-synthesis systems, which analyze a section of the input signal in the frequency domain after a time/frequency domain transformation, weight individual frequencies and then synthesize a time domain signal using an inverse transformation. These systems are particularly advantageous due to their computational efficiency, since convolution in the frequency domain and the time/frequency domain transformation can be implemented particularly cost-effectively using a fast Fourier transformation. However, these systems have a high delay due to frame-by-frame processing. In order to ensure high-performance ANC for non-deterministic signals, the delay in the signal path of the ANC filter must be as low as possible. In a transparency mode, the interference of passive sound and delayed active sound can lead to comb filter effects and the double perception of plosives. An analysis-synthesis system in the signal path is therefore unsuitable for such applications.

EP 1 538 749 A2 presents an alternative system, the so-called filter bank equalizer, which uses a time domain filter with a finite impulse response (FIR) to suppress interference from an input signal. The time domain filter results from the product of the impulse response of a prototype low-pass filter with an effective window function. The effective window function in turn results from the Fourier transformation of weighting factors for individual frequency bands. By using a time domain filter, the delay of the filter bank equalizer is significantly lower than that of an analysis-synthesis system. However, a time/frequency domain transformation is still necessary for the calculation of the filter. Thus, although there is no delay in the filtering itself, there is still a delay in the adjustment of the filter, which means that the approach can work incorrectly, especially with plosive sounds. A linear-phase prototype low-pass filter imposes a further delay, depending on the filter length. Furthermore, this approach can only implement FIR filters, which are often not supported by specialized processors with low delay. Furthermore, a filter bank with a nonlinear frequency resolution is only possible with this method by using many all-pass filters, which increases the computational complexity.

The disclosed embodiments provide a device and a corresponding method in which the audibility of the noise during the reproduction of an audio signal with a near-head audio output device, in particular headphones or a hearing aid, is reduced without noticeably changing the useful signal.

A disclosed device for reducing noise during the reproduction of an audio signal with a near-head audio output device, in particular a headphone or hearing aid, comprises
at least one sensor for detecting a sensor signal based on ambient sound and/or structure-borne sound;
a preprocessing unit for preprocessing the sensor signal or the sensor signals, wherein the preprocessing unit performs filtering and/or summation for active noise suppression, active suppression of the occlusion effect and/or an ambient mode;
a filter bank for dividing the sensor signal or the output signal of the preprocessing unit into frequency bands using several filters;
one or more calculation units for calculating weighting factors for the individual frequency bands, the weighting factors being calculated based on a measure of the signal of the sensor or the output signal of the pre-processing unit in the respective frequency band and a measure of the noise signal of the sensor or the output signal of the pre-processing unit in silence in this frequency band;
multipliers by which the individual frequency bands are multiplied by the corresponding calculated weighting factors;
an adder, by means of which the weighted output signals of the filter bank are summed to form a total output signal; and
an output unit for outputting a compensation signal based on the total output signal.

According to a preferred embodiment, the weighting factors are calculated based on the estimated power or standard deviation of the sensor signal or the output signal of the preprocessing unit in the respective frequency band and the estimated power or standard deviation of the noise signal of the sensor or the output signal of the preprocessing unit in silence in this frequency band.

According to yet another preferred embodiment, the preprocessing unit, the filters of the filter bank, the multipliers and the adder are implemented at a first sampling rate and the calculation units are implemented at a lower second sampling rate.

Advantageously, the preprocessing unit, the filters of the filter bank, the multipliers and the adder are implemented by a first processor.

Advantageously, the calculation units are implemented by a separate second processor.

In this case, the output signals of the respective filters of the filter bank are advantageously transmitted from the first processor to the second processor via an interface between the processors, and the calculated weighting factors for the individual bands of the filter bank are transmitted from the second processor back to the first processor.

According to one embodiment, the rate of the output signals of the filters of the filter bank is adapted to the sampling rate on the second processor by sampling rate converters.

According to a further embodiment, the input signal of the filter bank is transmitted from the first processor to the second processor via an interface between the processors, wherein the rate of the input signal to be transmitted is converted by a sampling rate converter and a second filter bank is simulated on the second processor for calculating the weighting factors, which realizes the filters at a correspondingly lower sampling rate and wherein the calculated weighting factors for the individual bands of the filter bank are transmitted from the second processor back to the first processor.

Preferably, the at least one sensor comprises one or more internal microphones arranged in an earpiece for detecting a sound signal in the ear canal of a user and/or external microphones for detecting a sound signal outside the ear canal and/or acceleration sensors for detecting structure-borne sound which is transmitted to the earpiece via the ear canal, and the output unit comprises at least one loudspeaker.

Furthermore, in one embodiment it can advantageously be provided that the filters of the filter bank are implemented by cascaded biquadratic filters as low-pass, high-pass and/or band-pass filters.

The device can be integrated into a near-head audio output device, in particular a headphone or hearing aid.

Accordingly, in a disclosed method for reducing noise during the reproduction of an audio signal with a near-head audio output device, in particular headphones or a hearing aid, the following steps are carried out:
detecting a sensor signal based on ambient sound and/or structure-borne sound with at least one sensor arranged in the headphones or hearing aid;
preprocessing the sensor signal or signals, wherein the preprocessing unit performs filtering and/or summation for active noise suppression, active suppression of the occlusion effect and/or an ambient mode:
applying noise suppression to the sensor signal or the output signal of the preprocessing unit, whereby the signal
   is divided into several frequency bands by means of a filter bank,
   the individual frequency bands are multiplied by weighting factors for the individual frequency bands, the weighting factors being calculated based on a measure of the signal of the sensor or the output signal of the pre-processing unit in the respective frequency band and a measure of the noise signal of the sensor or the output signal of the pre-processing unit in silence in that frequency band, and
   the weighted output signals of the filter bank are then summed to form an overall output signal; and
output of a compensation signal based on the total output signal.

The disclosure also relates to a computer program with instructions which cause a computer to carry out the steps of the disclosed method.

Further features of the present disclosure will become apparent from the following description and claims taken in conjunction with the figures.

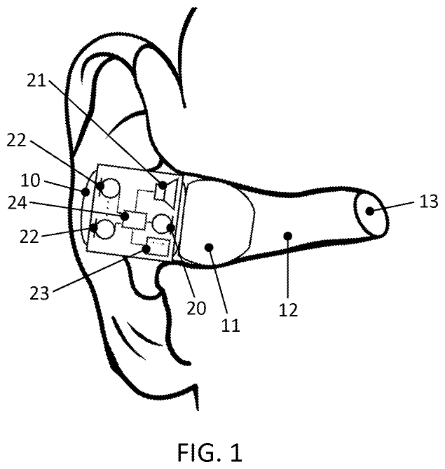

FIG. 1 shows a schematic of an in-ear headphone in the ear canal of a user with essential electronic components;

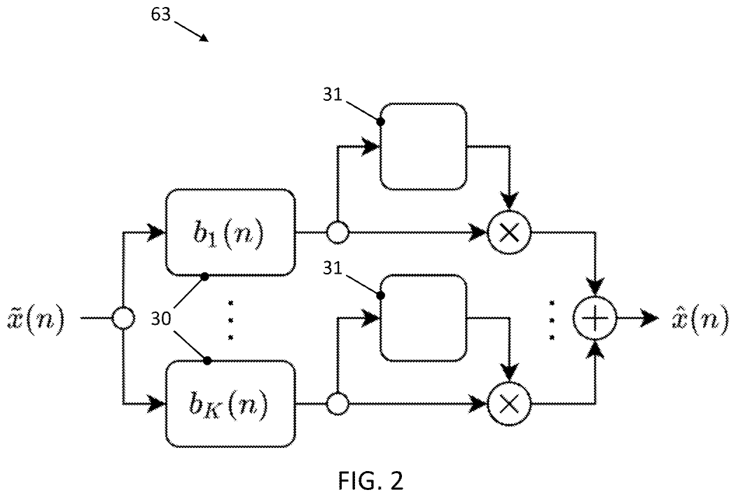

FIG. 2 shows a block diagram for a noise suppression with a filter bank in the time domain with one adaptation per band;

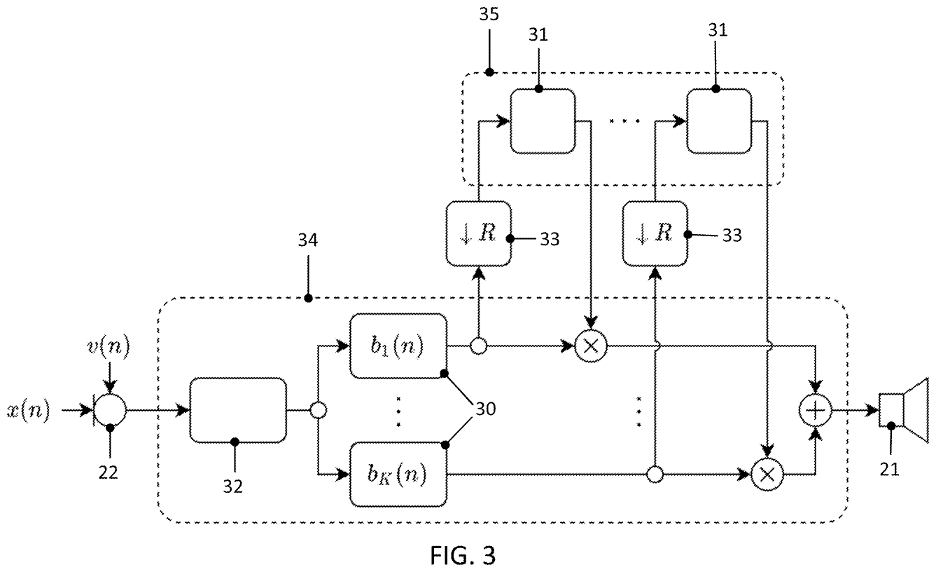

FIG. 3 shows a block diagram of a filtering system with noise suppression according to the disclosure;

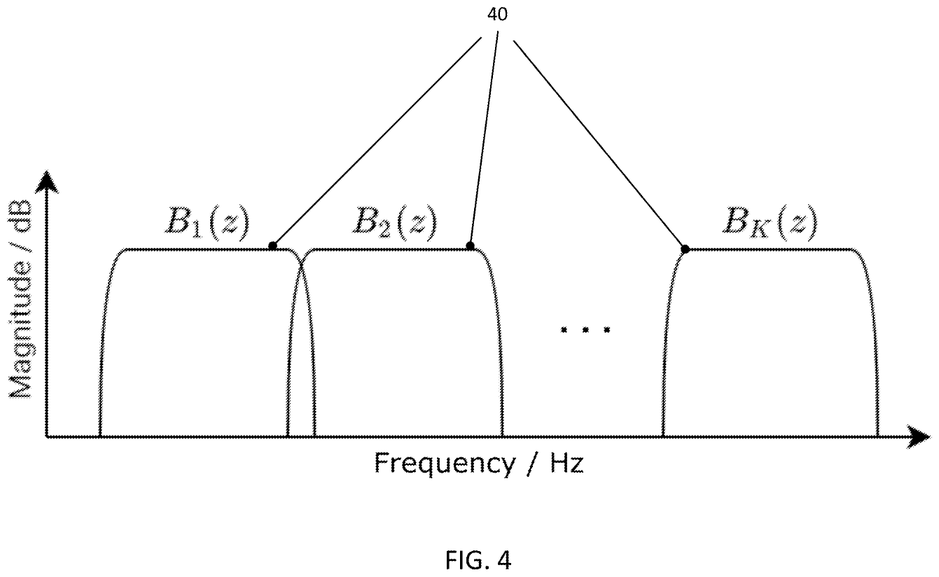

FIG. 4 shows schematically the magnitude response for a filter bank with bandpass filters;

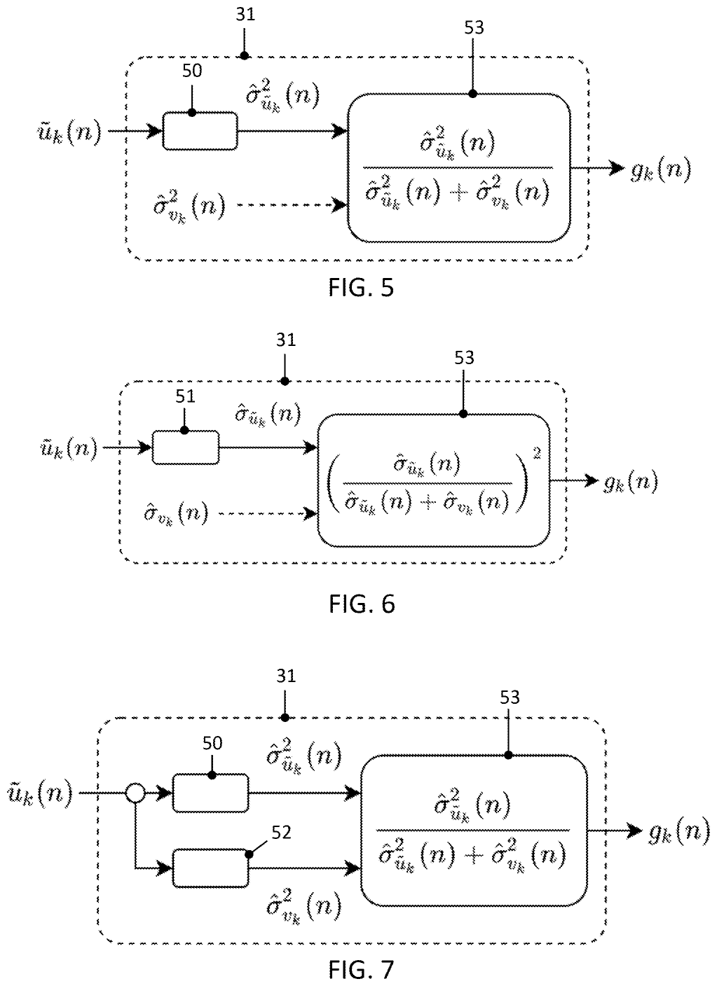

FIG. 5 shows a calculation unit for calculating a weighting factor per band;

FIG. 6 shows a calculation unit for the numerically robust calculation of a weighting factor per band;

FIG. 7 shows a calculation unit for calculating a weighting factor, where the noise power is estimated from the input signal;

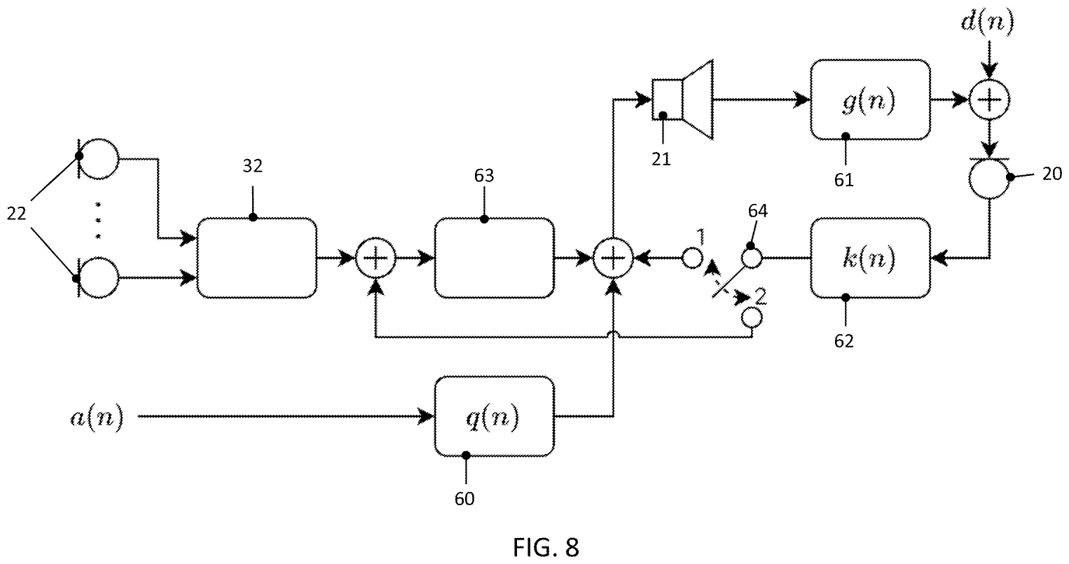

FIG. 8 shows a block diagram of a hybrid, multi-channel ANC system with noise cancellation;

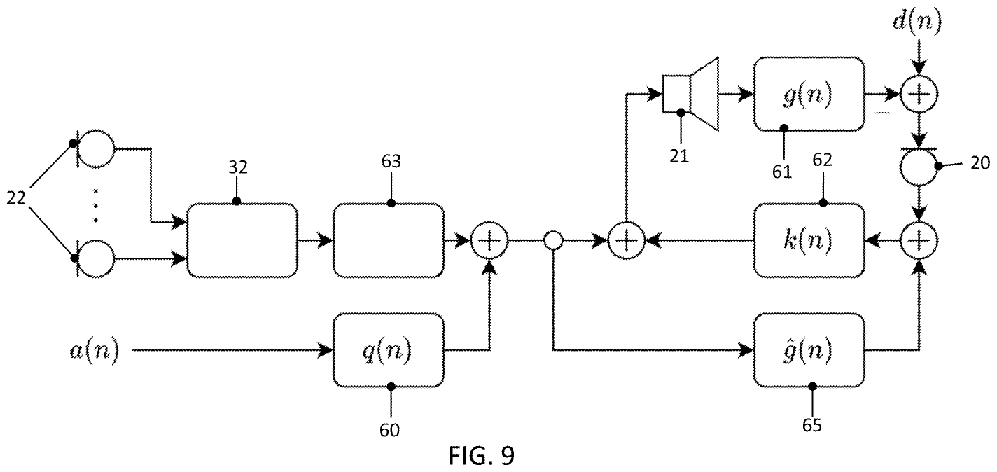

FIG. 9 shows a block diagram of a hybrid, multi-channel ANC system with noise reduction and feedback control loop compensation;

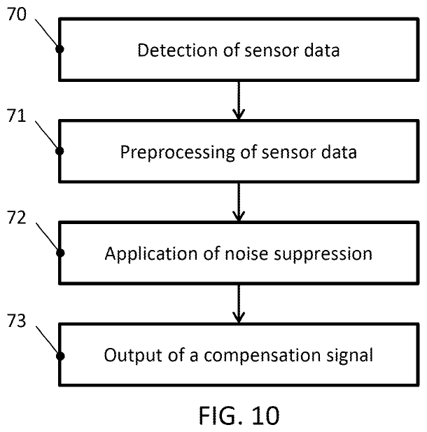

FIG. 10 shows a flow chart of a method according to the disclosure.

In order to better understand the principles of the present disclosure, embodiments are explained in more detail below with reference to the figures. It is understood that the disclosure is not limited to these embodiments and that the described features can also be combined or modified without departing from the scope of the disclosure as defined in the claims.

FIG. 1 shows an example of an in-ear headphone 10 for use with the disclosed device. However, the device can also be used in other types of audio output devices worn close to the head, such as headphones, hearing aids, smart glasses, VR/AR headsets, collar loudspeakers or bone conduction headphones. The in-ear headphone 10 is located in the ear canal 12, held by an ear insert 11, and acoustically seals it completely or partially. As a result, users can no longer perceive their surroundings clearly. In order to still allow users to hear their surroundings clearly when wearing headphones, the headphones are equipped with microphones 22 and at least one processor 24, which record the ambient sound, process it and reproduce it via the headphone's internal loudspeaker 21.

Closing off the ear canal 12 with headphones 10 also means that structure-borne noise, such as impact noise or speech, which is emitted into the ear canal 12 through vibrating ear canal walls, can hardly escape from the ear canal 12. This manifests itself in an amplification of low frequencies of the structure-borne noise compared to an open ear canal, which in combination with the weakened perception of ambient noise is referred to as the occlusion effect. To compensate for the occlusion effect (Active Occlusion Cancellation, AOC), additional sensors in the form of the inward-facing microphone 20 and the acceleration sensor 23 on the side of the headphones facing into the ear canal can be used to record information about the structure-borne noise in the ear canal 12.

In addition to generating acoustic transparency or compensating for the occlusion effect when wearing headphones, the sensors 20, 22, 23 and processors 24 can also be used to actively dampen loud ambient noise. With active noise suppression, an acoustic compensation signal is played via the headphone's internal loudspeaker 21 based on the sensor data, which destructively interferes with the ambient sound at the eardrum 13 and thus reduces the perceived volume of the ambient sound. Furthermore, the sensors can be used for an ambient mode in which ambient sound is processed and/or amplified, for example to improve speech intelligibility or compensate for hearing loss.

As already mentioned, a problem that is solved by the disclosed method is that the sensors not only record a useful signal x(n), with the discrete time index n, but also induce noise v(n). In the context of this disclosure, the useful signal includes not only speech but also ambient noise, some of which are considered undesirable in conventional methods for noise suppression, but here are assigned to the useful signal and not to the noise. The output signal of a sensor results from the sum of the useful signal and the sensor noise to

$$\tilde{x} ( n ) = x ( n ) + v ( n ) .$$

By processing and filtering the sensor signal, the noise can be significantly amplified, which can be perceived as unpleasant when played back by the loudspeaker for an AOC or ANC.

FIG. 2 shows a structure for noise suppression. The disturbed useful signal \tilde{x}(n) is first divided into different frequency ranges by a filter bank with K filters 30 with respective impulse responses bₖ(n) with k=1, 2, . . . , K. Each of the parallel process chains as a result of the filtering is referred to as a (frequency) band. The output signals of the filters 30 are each

$${\tilde{u}}_{k} ( n ) = {b}_{k} ( n ) * \tilde{x} ( n ) .$$

For each band k a time-variant weighting factor gₖ(n) is calculated in a calculation unit 31, which is then multiplied by the band signal ũₖ(n). At the output of the noise suppression 63, an estimate \tilde{x}(n) of the useful signal is then obtained, based on the weighted sum of the band signals:

$$\hat{x} ( n ) = {\sum }_{k = 1}^{K} {g}_{k} ( n ) \cdot {\tilde{u}}_{k} ( n ) \approx x ( n )$$

FIG. 3 shows a device according to the disclosure, wherein a useful signal x(n), such as ambient or structure-borne sound, is recorded by an external microphone 22 of a headphone 10, as shown byway of example in FIG. 1, and is additively disturbed by a noise v(n). The microphone signal is then processed on a processor for fast filtering 34, first by a preprocessing unit 32 and then filtered by a filter bank with filters 30 with the impulse responses bₖ(n). The individual bands are then weighted by weighting factors gₖ(n), wherein the weighting factors are calculated on one or more further processors 35. The output signals of the respective filters of the filter bank are transmitted via an interface from the processor for fast filtering to the further processor. The weighting factors for the individual bands of the filter bank are also transmitted via this interface from the further processor back to the processor for fast filtering.

The preprocessing unit can, for example, filter the microphone signal using a filter with the impulse response w(n), which is designed for a transparency or ambient mode, an ANC or AOC. Furthermore, the preprocessing unit can, for example, filter several sensor signals with different filters and then add them up to form an output signal.

The output signal is obtained with a filter w(n) as follows:

$$\hat{y} ( n ) = {\sum }_{k = 1}^{K} {g}_{k} ( n ) \cdot [ {b}_{k} ( n ) * w ( n ) * \tilde{x} ( n ) ] \approx w ( n ) * x ( n )$$

In order to achieve the lowest possible input-to-output latency on the processor for fast filtering 34, a high sampling rate is preferably used. The input-to-output latency should advantageously be less than 1 millisecond. Since the characteristics of the useful signal generally change only slowly, the calculation of the weighting factors can be carried out at a lower sampling rate. The calculation of the weighting factors can advantageously be carried out on one or more separate processors 35. In order to avoid aliasing effects when transferring the band signals to a lower sampling rate for calculating the weighting factors, a conversion of the sampling rate by sampling rate converters 33 is optionally provided. The weighting factors, on the other hand, do not require sampling rate conversion since the weighting factors are low-frequency signals.

Instead of converting the rate of the K output signals of the filters 30, the rate of the input signal of the filter bank can alternatively be converted and a second filter bank can be simulated on the processor or processors for calculating the weighting factors 35, which the filters 30 implement at a correspondingly lower sampling rate. The factors calculated in this way are then transmitted to the processor for fast filtering 34 as previously described and applied there. Since a filter bank on the processor is still necessary for fast filtering 34, this does not reduce the complexity of the processors 34, 35, but does reduce the number of sampling rate converters 33 and communication channels between the processors 34, 35.

FIG. 4 shows an example of the magnitude response 40 of the filter bank, with the filters 30 being implemented as bandpass filters. Each bandpass filter with the impulse response bₖ(n) should be designed in such a way that it ideally blocks the frequencies of an input signal below a lower limit frequency f_{g,k} and above an upper limit frequency f_{g,k+1} and allows frequencies between f_{g,k} and f_{g,k+1} to pass through without distortion. This results in the following target function for the magnitude response of a bandpass filter depending on the frequency f:

$$\vert {B}_{k} ( f ) \vert {=}^{!} \{ \begin{matrix}0 , if f < {f}_{g , k} \\ 1 , if {f}_{g , k} \leq f \leq {f}_{g , k + 1} \\ 0 , then\end{matrix}$$

Furthermore, the sum of the bandpass filters 30

$$\overline{B} ( z ) = {\sum }_{k = 1}^{K} {B}_{k} ( z )$$

should be advantageously optimized for the following objective function

$$\vert \overline{B} ( f ) \vert {=}^{!} \{ \begin{matrix}0 , if f < {f}_{g , 1} \\ 1 , if {f}_{g , 1} \leq f \leq {f}_{g , K + 1} \\ 0 , then\end{matrix} ,$$

so that there are no unwanted cancellations or amplifications, especially in the transition areas when the bandpass filters are connected in parallel. The lower cutoff frequency of the first bandpass filter f_{g,1} can be set equal to 0 Hz, commonly known as low-pass filter, and the upper cutoff frequency of the last bandpass filter f_{g,K+1} can be set equal to the Nyquist frequency, commonly known as high-pass filter. In order to carry out processing that mimics the human ear, it is advantageous to distribute the cutoff frequencies f_{g,k} linearly on a psychoacoustic frequency scale, e.g. the Bark scale. Furthermore, the filters 30 can advantageously be optimized such that the group delay of the transfer function B(z) is minimized, taking into account a target curve and a maximum deviation for the magnitude response.

Advantageously, the filters 30 can be realized as a cascade of biquadratic filters.

The filter bank therefore contributes only minimally to a delay in the signal path, which means that a high-performance ANC and a transparency mode without comb filter effects and without the double perception of plosives are still possible and can be calculated efficiently. Advantageously, the magnitude and phase response of B(z) is taken into account for the design of filters for an ANC or AOC, for example in a preprocessing unit 32.

However, an implementation corresponding to a quadrature filter bank is also possible. On the one hand, this leads to a filter bank with a linear frequency resolution and possibly an additional delay due to a sampling rate conversion in the signal path, but on the other hand to a reduction in the computational complexity.

The weighting factors can be specified based on a spectral subtraction rule using estimates of the short-term power of the disturbed wanted signal

$${\hat{σ}}_{\tilde{x}}^{2} ( n )$$

and the noise

$${\hat{σ}}_{ν}^{2} ( n ) .$$

The subtraction rule can be derived from the cost function, presented below independently of the band index k=1, 2, . . . , K

$$𝒞 = E \{ {[ x ( n ) - g ( n ) \cdot \tilde{x} ( n ) ]}^{2} \}$$

and results, assuming that the noise and the wanted signal are uncorrelated, in

$$g ( n ) = \frac{{\hat{σ}}_{\tilde{x}}^{2} ( n ) - {\hat{σ}}_{ν}^{2} ( n )}{{\hat{σ}}_{\tilde{x}}^{2} ( n )} .$$

This rule can cause the weighting factor to become negative, which leads to unwanted phase reflections. Therefore, it is usually assumed that 0≤g(n)≤1. A hard limitation of g(n) to this range of values can lead to undesirable temporal artifacts due to discontinuous changes. Depending on the estimated short-term power of the undisturbed wanted signal

$${\hat{σ}}_{x}^{2} ( n )$$

the mathematically optimal weighting factor is defined using the cost function [symbol] as

$$g ( n ) = \frac{{\hat{σ}}_{x}^{2} ( n )}{{\hat{σ}}_{x}^{2} ( n ) + {\hat{σ}}_{ν}^{2} ( n )} ,$$

whereby the desired range of values of g(n) is maintained. Unfortunately, x(n) and thus also

$${\hat{σ}}_{x}^{2} ( n )$$

are not known.

Since the power of sensor noise is usually small compared to the power of a useful signal, it can be assumed that

$${\hat{σ}}_{\tilde{x}}^{2} ( n ) \approx {\hat{σ}}_{x}^{2} ( n ) ,$$

when a useful signal is present, which results in the calculation rule of block 53 in the calculation unit 31 according to FIG. 5 for a band k. The power of the sensor and quantization noise is usually constant, so

$${\hat{σ}}_{{ν}_{k}}^{2} ( n ) = {\hat{σ}}_{{ν}_{k}}^{2}$$

can be determined for each band, e.g. by measuring in silence, listening tests, taking component specifications into account, estimating in a quiet environment during runtime or using mathematical methods. The sensor and quantization noise is also commonly known as system noise or noise floor. For a measurement in silence, for example, the digitized signals of the sensors 20, 22, 23 or the output signal of the preprocessing unit 32 can be recorded, wherein the headphones 10 are activated and located in a room acoustically protected from ambient noise. Advantageously, the values \hat{σ}ᵥ_{ₖ}²(n) can be selected such that a specific useful signal, with a selected sound pressure level at one of the sensors 20, 22, 23 or a separate reference sensor, results in a specific maximum attenuation. This therefore differs from the goal of typical hearing aid processing, in which ambient noise is reduced in order to extract voice signals. The estimated short-term power

$${\hat{σ}}_{{\tilde{u}}_{k}}^{2} ( n )$$

of the input signal ũₖ(n) can, for example, be calculated by a block 50 using an exponential smoother with a smoothing factor 0<<λ<1 based on

$${\hat{σ}}_{{\tilde{u}}_{k}}^{2} ( n ) = λ \cdot {\hat{σ}}_{{\tilde{u}}_{k}}^{2} ( n - 1 ) + ( 1 - λ ) \cdot {\tilde{u}}_{k}^{2} ( n )$$

For reasons of cost and battery efficiency, integrated systems such as headphones often use processors that only have fixed-point arithmetic. The division operation in particular is numerically poorly conditioned, which is why it is desirable to reduce the dynamics of the input values of the division operation when calculating the weighting factor. This can be achieved by the calculation unit 31 shown in FIG. 6 by using the standard deviation, or the square root of the variance of the signal, σ(n), instead of the corresponding short-term power σ²(n) and then squaring the quotient using block 53. Neglecting the cross term of the binomial formula, this calculation rule of block 53 is equivalent to the previous calculation rule of block 53 from FIG. 5. An estimate of the standard deviation can again be calculated by a block 51 using an exponential smoother based on

$${\hat{σ}}_{{\tilde{u}}_{k}} ( n ) = λ \cdot {\hat{σ}}_{{\tilde{u}}_{k}} ( n - 1 ) + ( 1 - λ ) \cdot \vert {\tilde{u}}_{k} ( n ) \vert$$

As shown in FIG. 7, the short-term power

$${\hat{σ}}_{{ν}_{k}}^{2} ( n )$$

of the noise signal can be estimated based on the output signals of the filters 30 ũₖ(n). For this purpose, established algorithms such as the so-called baseline tracer can be used in block 52, which are based on the assumption that the power of the noise is quasi time-invariant and can be estimated in pauses in the useful signal. These methods can be used to estimate the system noise in the running system when a quiet environment is detected. In contrast to hearing aid applications, the goal here is not to detect ambient noise, but to detect the system noise.

Furthermore, it is possible to set the weighting factors gₖ(n) so that the power of the respective weighted bandpass signals does not exceed a specified threshold. This can be used to protect the hearing of users in noisy environments.

FIG. 8 shows a further embodiment of the device according to the disclosure, which comprises M external microphones 22, a microphone 20 directed into the ear canal and a loudspeaker 21. In addition to or instead of the external microphones 22 or the internal microphone 20, one or more acceleration sensors 23 can also be used. The signal from the microphone 20 directed into the ear canal is fed to a filter 62 k(n) which can be designed, for example, to dampen ambient or structure-borne noise d(n) in certain frequency ranges. For the design of a feedback filter 62, the secondary path 61 with the impulse response g(n), which characterizes the transfer function between the loudspeaker 21 and the inner microphone 20, must be taken into account in particular. The signals from the external microphones 22 are fed to the preprocessing unit 32, which filters the microphone signals, for example, with a filter wₘ(n) mit m=1, 2, . . . , M, and then sums them up. The filters can be designed for a transparency or ambient mode, an ANC or AOC. By filtering and then summing several microphones, the pre-processing unit can, for example, implicitly implement a filter-and-sum beamformer, which processes the signals of a microphone array, for example, so that the output signal mainly only includes sound from certain directions. The output signal of the pre-processing unit is then fed to the noise suppression 63 according to FIG. 3. The preprocessing unit 32 and the feedback filter 62 are still implemented at a high sampling rate, for example on a processor for fast filtering, whereas the calculation units for calculating the weighting factors for the noise suppression 63 are implemented at a lower sampling rate, for example on one or more separate processors. The output signal of the feedback filter 62 can be fed by the switch 64 either to the sum of the loudspeaker signal (switch position 1) or to the sum of the input signal for the noise suppression 63 (switch position 2). Furthermore, the reproduction of a multimedia signal a(n), such as music or speech from a telephone call, is provided, which is equalized by an equalizer 60 with the impulse response q(n). The output signal of the equalizer is passed on directly to the loudspeaker 21 together with the output signal of the feedback filter 62 and the noise suppression 63.

FIG. 9 shows a further embodiment of the device according to the disclosure, which, like the embodiment of FIG. 8, has several external microphones 22 and filters 32 for filtering, a microphone 20 directed into the ear canal and a feedback filter 62, a loudspeaker 21, a multimedia signal a(n) and an equalizer 60. In contrast to the embodiment of FIG. 8, this embodiment contains an estimate of the secondary path 65 with the impulse response ĝ(n), to which the sum of the equalized multimedia signal and the denoised signal is fed. The output signal of the secondary path estimate 65 is added to the signal of the inner microphone 20, so that the closed control loop formed by the feedback filter 62 and the secondary path 61 has only a reduced effect on the signals fed to the secondary path estimate 65. Otherwise, the transmission behavior to the inner microphone 20 as well as to the eardrum 13 would audibly change depending on the feedback filter 62.

The device according to the disclosure can in particular be integrated into headphones, whereby such headphones can be designed in various ways. For example, they can be earphones, hearables, or so-called in-ear monitors, which are used, for example, during live performances by musicians or TV presenters to check one's own voice, or a combination of headphones and a mouth microphone for recording speech in the form of a headset. The device can also be part of a hearing aid. In addition, the device can be integrated into smart glasses, VR/AR headsets, collar loudspeakers or bone conduction headphones. Finally, parts of the device can also be part of an external device, such as a smartphone.

FIG. 10 shows schematically the basic concept for a method for reducing noise during the reproduction of an audio signal, as can be carried out, for example, using a device from FIG. 3. In the following, reference is made by way of example to the application of the method to headphones, but the method is not limited to this and can also be used with other head-mounted audio output devices, in particular with a hearing aid.

In the method, in a first step 70, ambient sound and/or structure-borne sound, which originates, for example, from a voice output of the user wearing the headphones or footsteps of this user, is recorded using at least one sensor arranged in the headphones. The corresponding sensor signals are processed in a subsequent step 71 by means of a preprocessing unit, which carries out filtering and/or summation for active noise suppression, active suppression of the occlusion effect and/or an ambient mode. In the subsequent step 72, the sensor signal or the output signal of the preprocessing unit is then subjected to noise suppression. The method uses a filter bank which is integrated into the signal path between the sensors and the loudspeaker of the headphones. The filtered sensor signal is divided into several frequency bands using the filter bank.

An algorithm sets weighting factors, which are multiplied by the respective output signals of the filter bank, so that frequency bands in which there is hardly any useful signal are noticeably attenuated. In particular, the weighting factors can be calculated based on a measure of the signal from the sensor or the output signal from the preprocessing unit (32) in the respective frequency band and a measure of the noise signal from the sensor or the output signal from the preprocessing unit (32) in silence in this frequency band. The weighted output signals of the filter bank are then summed to form an overall output signal.

In the subsequent step 73, a compensation signal based on the total output signal is then fed to a loudspeaker of the headphones and output by the latter.

In the case of headphones that include sound transducers for both ears of the user, the described procedure can be carried out separately for each ear or together for the sound transducers of both ears.

### REFERENCE SYMBOL LIST

10 In-ear headphones
11 Ear insert
12 Ear canal
13 Eardrum
20 Inner microphone
21 Loudspeaker
22 External microphone
23 Acceleration sensor
24 Signal processor
30 Filter
31 Calculation unit for weighting factor
32 Preprocessing unit
33 Sampling rate converter
34 Processor for fast filtering
35 Processor for calculating the weighting factors
40 Magnitude response of a filter
50 Power estimator of the useful signal
51 Estimator of the standard deviation of the useful signal
52 Power estimator of the noise signal
53 Block with calculation rule
60 Equalizer
61 Secondary path
62 Filter
63 Noise reduction
64 Switch for the filter output signal
65 Estimation of the secondary path
70 Process step for collecting the sensor data
71 Process step for filtering the sensor data
72 Process step for applying noise reduction
73 Process step for outputting a compensation signal

1. Device for reducing noise when reproducing an audio signal with a near-head audio output device, in particular headphones or a hearing aid, with
at least one sensor for detecting a sensor signal based on ambient sound and/or structure-borne sound;
a preprocessing unit for preprocessing the sensor signal or the sensor signals, wherein the preprocessing unit carries out filtering and/or summation for active noise suppression, active suppression of the occlusion effect and/or an ambient mode;
a filter bank for dividing the sensor signal or the output signal of the preprocessing unit into frequency bands using a plurality of filters;
one or more calculation units for calculating weighting factors for the individual frequency bands, the weighting factors being calculated based on a measure of the signal of the sensor or the output signal of the preprocessing unit in the respective frequency band and a measure of the noise signal of the sensor or the output signal of the preprocessing unit in silence in this frequency band;
multipliers, by means of which the individual frequency bands are multiplied by the associated calculated weighting factors;
an adder, by means of which the weighted output signals of the filter bank are summed to form an overall output signal; and
an output unit for outputting a compensation signal based on the overall output signal.

2. Device according to claim 1, wherein the weighting factors are calculated based on the estimated power or standard deviation of the sensor signal or the output signal of the preprocessing unit in the respective frequency band and the estimated power or standard deviation of the noise signal of the sensor or the output signal of the preprocessing unit in silence in this frequency band.

3. Device according to claim 1, wherein the preprocessing unit, the filters of the filter bank, the multipliers and the adder are implemented at a first sampling rate and the calculation units are implemented at a lower second sampling rate.

4. Device according to claim 3, wherein the preprocessing unit, the filters of the filter bank, the multipliers and the adder are implemented by a first processor.

5. Device according to claim 4, wherein the calculation units are implemented by a second processor separate therefrom.

6. Device according to claim 5, wherein the output signals of the respective filters of the filter bank are transmitted from the first processor to the second processor via an interface between the processors and the calculated weighting factors for the individual bands of the filter bank are transmitted from the second processor back to the first processor.

7. Device according to claim 6, wherein the rate of the output signals of the filters of the filter bank is adapted to the sampling rate on the second processor by sampling rate converters.

8. Device according to claim 5, wherein the input signal of the filter bank is transmitted from the first processor to the second processor via an interface between the processors, wherein the rate of the input signal to be transmitted is converted by a sampling rate converter and a second filter bank is simulated on the second processor for calculating the weighting factors, which realizes the filters at a corresponding lower sampling rate and wherein the calculated weighting factors for the individual bands of the filter bank are transmitted from the second processor back to the first processor.

9. Device according to claim 1, wherein the at least one sensor comprises one or more internal microphones arranged in an earpiece for detecting a sound signal in the ear canal of a user and/or external microphones for detecting a sound signal outside the ear canal and/or acceleration sensors for detecting structure-borne sound which is transmitted to the earpiece via the ear canal, and the output unit comprises at least one loudspeaker.

10. Device according to claim 1, wherein the filters of the filter bank are realized by cascaded biquadratic filters as low-pass, high-pass and/or band-pass filters.

11. Device according to claim 1, wherein it is integrated in a near-head audio output device, in particular a headphone or hearing aid.

12. Method for reducing noise when reproducing an audio signal with a near-head audio output device, in particular headphones or a hearing aid, with the steps:
detecting a sensor signal based on ambient sound and/or structure-borne sound with at least one sensor arranged in the headphones or hearing aid;
preprocessing the sensor signal or the sensor signals, wherein filtering and/or summation is carried out for active noise suppression, active suppression of the occlusion effect and/or an ambient mode;
applying noise suppression to the sensor signal or the output signal of the preprocessing unit, wherein the signal
is divided into several frequency bands by means of a filter bank,
the individual frequency bands are multiplied by weighting factors for the individual frequency bands, wherein the weighting factors are calculated based on a measure of the signal of the sensor or the output signal of the preprocessing unit in the respective frequency band and a measure of the noise signal of the sensor or the output signal of the preprocessing unit in silence in this frequency band, and
the weighted output signals of the filter bank are then summed to form an overall output signal; and
outputting a compensation signal based on the overall output signal.
